(19) United States
(12) Patent Application Publication
(10) Pub. No.: US 2026/0164675 A1
(43) Pub. Date: Jun. 11, 2026

(54) SEMICONDUCTOR DEVICE AND MANUFACTURING METHOD OF THE SEMICONDUCTOR DEVICE

(71) Applicant: SK hynix Inc., Icheon-si (KR)

(72) Inventor: Jeong Hoon BAE, Icheon-si (KR)

(21) Appl. No.: 19/181,045

(22) Filed: Apr. 16, 2025

(30) Foreign Application Priority Data
Aug. 27, 2024 (KR) 10-2024-0114981

(51) Int. Cl. H10B 63/00; H10N 70/00

(52) U.S. Cl. CPC H10B 63/80; H10N 70/063

(57) ABSTRACT

A semiconductor device may include: a first row line extending in a first direction and including a first sidewall extending in the first direction and a second sidewall extending in a second direction intersecting the first direction, the second sidewall exhibiting greater surface roughness than the first sidewall; a column line extending in the second direction; and a first memory cell connected to and disposed between the first row line and the column line.

### CROSS-REFERENCE TO RELATED APPLICATION

This application claims priority under 35 U.S.C. § 119 to Korean Patent Application No. 10-2024-0114981 filed on Aug. 27, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

Recently, in accordance with miniaturization, low power consumption, performance improvement, diversification, and the like, of electronic devices, semiconductor devices capable of storing information have been demanded in various electronic devices such as computers and portable communication devices. Accordingly, research into a semiconductor device capable of storing data using characteristics of switching between different resistance states depending on an applied voltage or current has been conducted. Examples of such a semiconductor device include a resistive random access memory (RRAM), a phase-change random access memory (PRAM), a ferroelectric random access memory (FRAM), a magnetic random access memory (MRAM), and the like.

### SUMMARY

In an embodiment, a semiconductor device may include: a first row line extending in a first direction and including a first sidewall extending in the first direction and a second sidewall extending in a second direction intersecting the first direction, the second sidewall exhibiting greater surface roughness than the first sidewall; a column line extending in the second direction; and a first memory cell connected to and disposed between the first row line and the column line.

In an embodiment, a manufacturing method of a semiconductor device may include: forming a sacrificial layer; forming a cell stack on the sacrificial layer in a third direction, the cell stack including a variable resistance layer; etching the cell stack to form cell lines that extend in a first direction perpendicular to the third direction; etching the sacrificial layer to form sacrificial lines that extend in the first direction; forming first gap-fill insulating layers between the cell lines and between the sacrificial lines; and replacing the sacrificial lines with row lines.

In an embodiment, a manufacturing method of a semiconductor device may include: forming a sacrificial layer; forming a cell stack on the sacrificial layer in a third direction, the cell stack including a variable resistance layer; etching the cell stack to form cell lines that extend in a first direction; etching the sacrificial layer to form sacrificial lines that extend in the first direction; etching the cell lines and the sacrificial lines to form a first trench that extend in a second direction intersecting the first direction, the first and second directions being perpendicular to the third direction; removing the sacrificial lines exposed through the first trench to form openings; forming a conductive layer in the openings; and forming row lines by removing the conductive layer in the first trench, the row lines corresponding to the conductive layer remaining in the openings, respectively.

### BRIEF DESCRIPTION OF THE DRAWINGS

FIGS. 1A to 1C illustrate a semiconductor device in accordance with an embodiment.

FIGS. 2A, 3A, 4A, 5A, 6A, and 7A, FIGS. 2B, 3B, 4B, 5B, 6B, and 7B, and FIGS. 2C, 3C, 4C, 5C, 6C, and 7C describe a manufacturing method of a semiconductor device in accordance with an embodiment.

FIGS. 8A, 9A, 10A, 11A, 12A, 13A, and 14A, FIGS. 8B, 9B, 10B, 11B, 12B, 13B, and 14B, and FIGS. 8C, 9C, 10C, 11C, 12C, 13C, and 14C describe a manufacturing method of a semiconductor device in accordance with an embodiment.

### DETAILED DESCRIPTION

Various embodiments are directed to a semiconductor device with a stable structure and enhanced performance characteristics, and to a manufacturing method of the semiconductor device.

Forming memory cells in a cross point array can enhance the degree of integration of a semiconductor device. Additionally, it allows for a semiconductor device with a stable structure and improved reliability.

Hereafter, embodiments in accordance with the technical spirit of the present disclosure will be described with reference to the accompanying drawings.

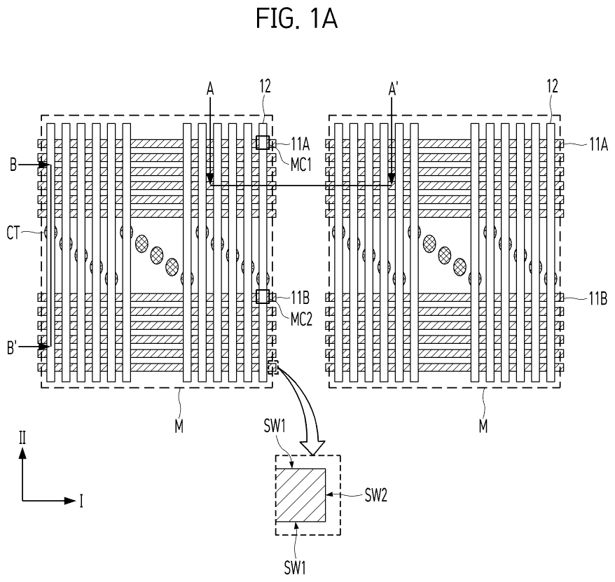

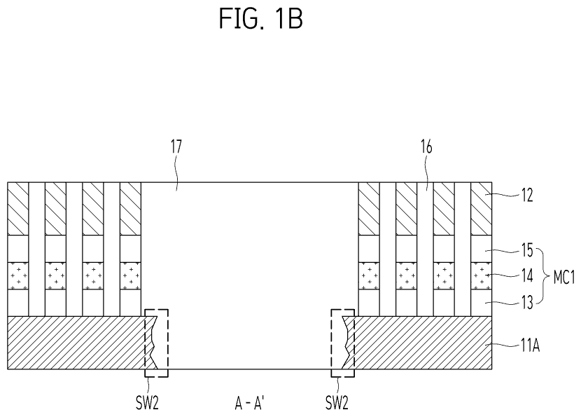

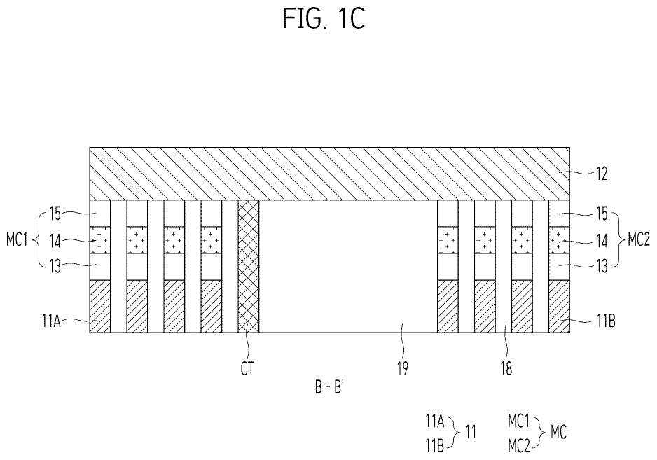

FIGS. 1A to 1C illustrate a semiconductor device in accordance with an embodiment. FIG. 1A is a layout diagram, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include mats M. Here, each of the mats M may function as a driving unit that allows for independent write and read operations. A plurality of mats M may be arranged in a first direction I and a second direction II, which intersects the first direction I.

The semiconductor device may include row lines 11, column lines 12, and memory cells MC. For example, the semiconductor device may include first row lines 11A, column lines 12, and first memory cells MC1. The semiconductor device may further include one or more of second row lines 11B, second memory cells MC2, contact plugs CT, a first gap-fill insulating layer 18, a second gap-fill insulating layer 17, a third gap-fill insulating layer 19, and a fourth gap-fill insulating layer 16. The first row lines 11A, the second row lines 11B, and the column lines 12 may be separated in mat M units.

The first row lines 11A may extend in the first direction I. The first row lines 11A may be word lines or bit lines. The second row lines 11B may be spaced apart from the first row lines 11A in the second direction II, and may extend in the first direction I.

Each of the first row lines 11A may include a first sidewall SW1 extending in the first direction I and a second sidewall SW2 extending in the second direction II. The first sidewall SW1 and the second sidewall SW2 may have different levels of surface roughness. The first sidewall SW1 may have a deposition surface formed by a deposition process, while the second sidewall SW2 may have an etched surface formed by an etching process. The difference in surface roughness between the first sidewall SW1 and the second sidewall SW2 may result from the variations in these processes. For example, the second sidewall SW2 may exhibit greater surface roughness than the first sidewall SW1.

Each of the second row lines 11B may have a similar structure to each of the first row lines 11A. Each of the second row lines 11B may include a first sidewall extending in the first direction I and a second sidewall extending in the second direction II, with the second sidewall exhibiting greater surface roughness than the first sidewall.

The column lines 12 may extend in the second direction II. The column lines 12 may be bit lines or word lines. For example, the first and second row lines 11A and 11B may be word lines and the column lines 12 may be bit lines. The column lines 12 may intersect the first row lines 11A and the second row lines 11B.

The first memory cells MC1 may be connected between the first row lines 11A and the column lines 12. First memory cells MC1 located at both ends of the first row lines 11A in the first direction I among the first memory cells MC1 may be dummy memory cells. For example, first memory cells MC1 located at edges of the mat M may be dummy memory cells. A dummy memory cell may include a damaged variable resistance layer.

The second memory cells MC2 may be connected between the second row lines 11B and the column lines 12. Second memory cells MC2 located at both ends of the second row lines 11B in the first direction I among the second memory cells MC2 may be dummy memory cells. A dummy memory cell may include a damaged variable resistance layer.

The contact plugs CT may be located between the first row lines 11A and the second row lines 11B, which are adjacent to each other in the second direction II. Each contact plug CT may be arranged in a direction intersecting the first direction I and the second direction II. For example, the contact plugs CT may be arranged in a diagonal direction of the first and second directions I and II. The column lines 12 may be connected to the contact plugs CT, respectively.

Each of the first memory cells MC1 may include at least one of a select element or a memory element. For example, each of the first memory cells MC1 may include a first electrode 13, a variable resistance layer 14, and a second electrode 15. The variable resistance layer 14 may be located between the first electrode 13 and the second electrode 15 in a third direction that is perpendicular to both the first and second directions.

The variable resistance layer 14 may have characteristics that allow it to reversibly transition between different resistance states depending on a voltage or a current applied to the first memory cell MC1. For example, when the variable resistance layer 14 is in a low resistance state, it may store data ‘1,’ whereas in a high resistance state, it may store data ‘0.’

For example, the variable resistance layer 14 may include a resistive material. An electrical path is generated or disappears within the variable resistance layer 14, such that data may be stored. For example, the variable resistance layer 14 may include a transition metal oxide or a metal oxide, such as a perovskite-based material.

For example, the variable resistance layer 14 may have a magnetic tunnel junction (MTJ) structure including a magnetization pinned layer, a tunnel barrier layer, and a magnetization free layer. The variable resistance layer 14 may store data based on changes in the magnetization direction of the magnetization free layer relative to the magnetization direction of the magnetization pinned layer. For example, the magnetization pinned layer and the magnetization free layer may each include a magnetic material, while the tunnel barrier layer may include a metal oxide.

For example, the variable resistance layer 14 may include a phase change material or a chalcogenide-based material. The variable resistance layer 14 may undergo a phase change during a program operation. For an example, the variable resistance layer 14 may transition to a low resistance crystalline state through a set operation, while the variable resistance layer 14 may transition to a high resistance amorphous state through a reset operation. Accordingly, data may be stored in the memory cell based on the resistance difference associated with the phase of the variable resistance layer 14.

For example, the variable resistance layer 14 may include a variable resistance material whose resistance changes without undergoing a phase change, or it may include a chalcogenide-based material. The variable resistance layer 14 may maintain its phase after the program operation. For example, the variable resistance layer 14 may be in an amorphous state and retain the amorphous state without transitioning to a crystalline state after the program operation. A threshold voltage of the memory cell may vary depending on a program voltage applied to the memory cell, allowing the memory cell to be programmed to at least two states. For example, the memory cell may be programmed to a set state or a reset state using program voltages with different polarities. Accordingly, data may be stored in the memory cell based on a difference in the threshold voltage.

The first electrode 13 may be electrically connected to the first row line 11A. The second electrode 15 may be electrically connected to the column line 12. The first electrode 13 and the second electrode 15 may each include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), aluminum (Al), copper (Cu), zinc (Zn), nickel (Ni), cobalt (Co), lead (Pb), platinum (Pt), molybdenum (Mo), ruthenium (Ru), or the like, or include combinations thereof.

The second memory cells MC2 may each have a structure similar to that of the first memory cell MC1. Each of the second memory cells MC2 may include a first electrode 13, a variable resistance layer 14, and a second electrode 15. The variable resistance layer 14 may be located between the first electrode 13 and the second electrode 15 in the third direction.

The first gap-fill insulating layers 18 may be located between the first row lines 11A, between the first memory cells MC1, between the second row lines 11B, and between the second memory cells MC2. The second gap-fill insulating layer 17 may be located between the mats M adjacent to each other in the first direction I. The third gap-fill insulating layer 19 may be located between the first row line 11A and the second row line 11B, as well as between the first memory cell MC1 and the second memory cell MC2, which are adjacent to each other in the second direction II. The fourth gap-fill insulating layers 16 may be located between the column lines 12, between the first memory cells MC1, and between the second memory cells MC2. The second gap-fill insulating layer 17 and the third gap-fill insulating layer 19 may be connected to each other, forming a cross shape.

According to the structure described above, the semiconductor device may include a cell array arranged in the form of a cross point array. The mat M may include the first row lines 11A, the second row lines 11B, the first memory cells MC1, the second memory cells MC2, and the column lines 12. Here, the first and second row lines 11A and 11B may be formed by replacing sacrificial layers with conductive layers, and the surface roughness of the first sidewall SW1 and the second sidewall SW2 of each of the first and second row lines 11A and 11B may differ from each other. Because the first and second row lines 11A and 11B are formed using a replacement process, damage to the variable resistance layer 14 during a manufacturing process may be reduced, thereby improving the reliability of the semiconductor device.

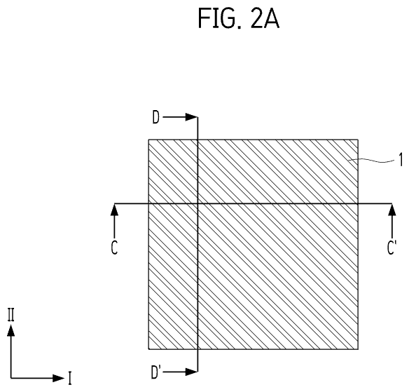

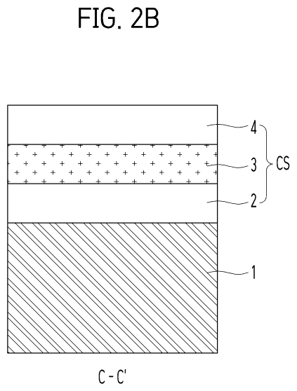

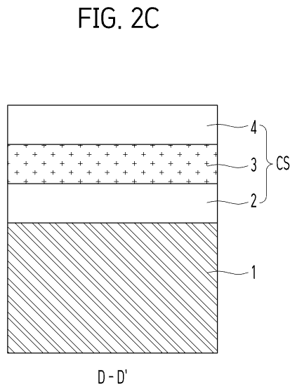

FIGS. 2A, 3A, 4A, 5A, 6A, and 7A, FIGS. 2B, 3B, 4B, 5B, 6B, and 7B, and FIGS. 2C, 3C, 4C, 5C, 6C, and 7C describe a manufacturing method of a semiconductor device in accordance with an embodiment. FIGS. 2A, 3A, 4A, 5A, 6A, and 7A are layout diagrams, FIGS. 2B, 3B, 4B, 5B, 6B, and 7B are cross-sectional views taken along lines C-C′ of FIGS. 2A, 3A, 4A, 5A, 6A, and 7A, and FIGS. 2C, 3C, 4C, 5C, 6C, and 7C are cross-sectional views taken along lines D-D′ of FIGS. 2A, 3A, 4A, 5A, 6A, and 7A. Hereinafter, the content overlapping with the previously described content may be omitted.

Referring to FIGS. 2A to 2C, a sacrificial layer 1 may be formed over a substrate (not shown). The sacrificial layer 1 may be used to be replaced with row lines in a subsequent process. The sacrificial layer 1 may include a material with high etching selectivity relative to a first electrode layer 2, a variable resistance layer 3, and a second electrode layer 4, which are stacked on top of the sacrificial layer 1. For example, the sacrificial layer 1 may include nitride.

Subsequently, a cell stack CS including the variable resistance layer 3 may be formed on the sacrificial layer 1. For example, the cell stack CS may include the first electrode layer 2, the variable resistance layer 3, and the second electrode layer 4, and the variable resistance layer 3 may be located between the first electrode layer 2 and the second electrode layer 4 in the third direction.

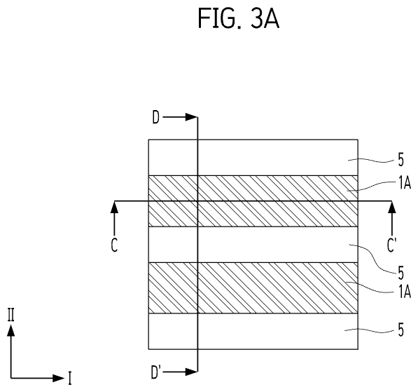

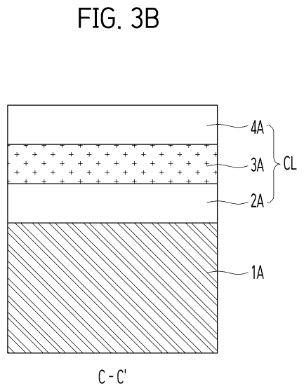

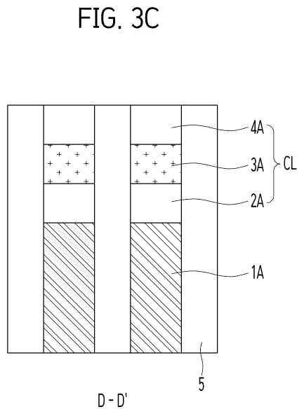

Referring to FIGS. 3A to 3C, cell lines CL may be formed by etching the cell stack CS. The cell lines CL may extend in the first direction I. Each of the cell lines CL may include a first electrode line 2A, a variable resistance line 3A, and a second electrode line 4A.

Subsequently, sacrificial lines 1A may be formed by etching the sacrificial layer 1. The sacrificial lines 1A may extend in the first direction I. Chemicals used in an etching process of the sacrificial layer 1 may not include fluorine (F) and chlorine (Cl). Accordingly, it is possible to reduce damage to the variable resistance line 3A in a process of etching the sacrificial layer 1.

Subsequently, first gap-fill insulating layers 5 may be formed between the cell lines CL and between the sacrificial lines 1A. The first gap-fill insulating layers 5 may extend in the first direction I. For example, the first gap-fill insulating layers 5 may each include an insulating material such as oxide.

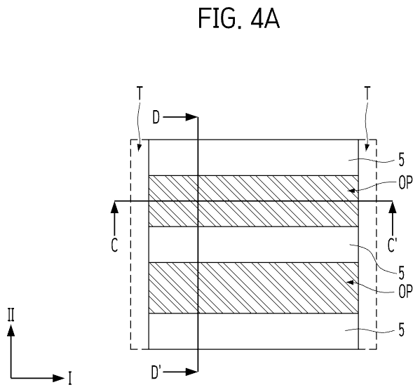

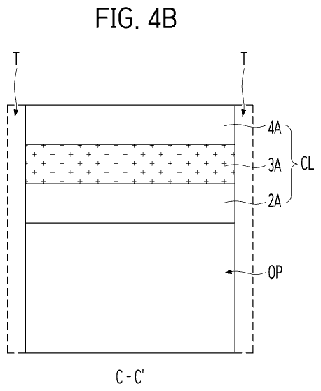

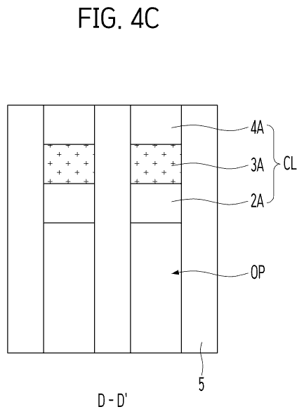

Referring to FIGS. 4A to 4C, openings OP may be formed by removing the sacrificial lines 1A. For example, trenches T extending in the second direction II and exposing the sacrificial lines 1A may be formed. Subsequently, the sacrificial lines 1A may be removed in the first direction I through the trenches T using a selective wet etching process. Although the sacrificial lines 1A beneath the cell lines CL are removed, the cell lines CL may still be supported by the first gap-fill insulating layers 5.

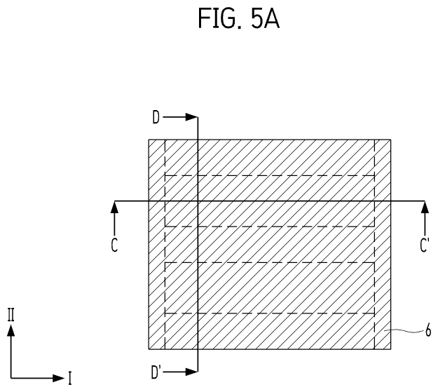

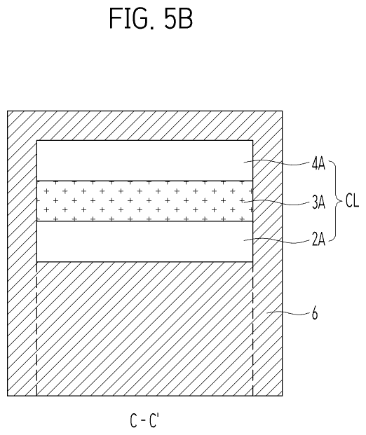

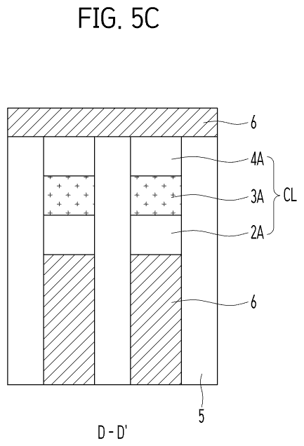

Referring to FIGS. 5A to 5C, a conductive layer 6 may be formed to fill the openings OP. For example, a conductive material may be deposited along inner surfaces of the openings OP to fill the openings OP. The conductive material may also be deposited on surfaces of the cell lines CL and surfaces of the first gap-fill insulating layers 5. The conductive layer 6 may fill the openings OP and extend into the trenches T. The conductive layer 6 may include a metal such as tungsten or molybdenum.

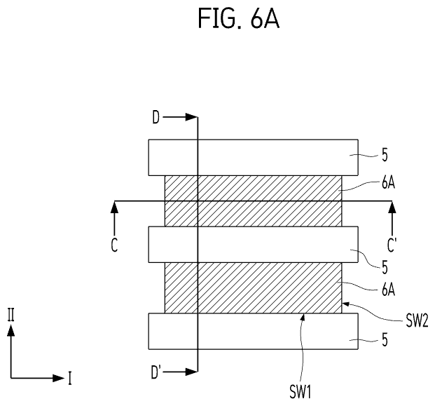

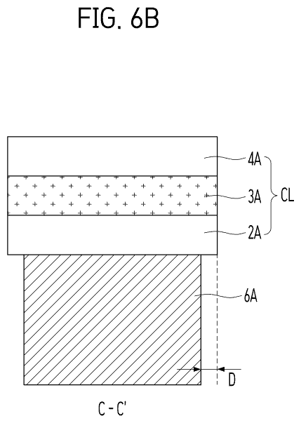

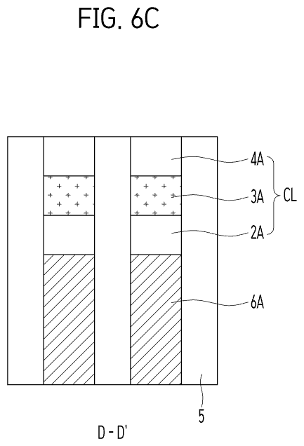

Referring to FIGS. 6A to 6C, row lines 6A may be formed by etching the conductive layer 6. The conductive layer 6 deposited in the trench T is removed and the row lines 6A that correspond to the conductive layer 6 remaining in the openings OP are formed. The conductive layer 6 may be wet-etched using chemicals including a Group XVII element. These chemicals may include fluorine (F), chlorine (Cl), or both. In a process of etching the conductive layer 6 using the chemicals including the Group XVII element, the variable resistance line 3A may be partially damaged. A sidewall of the variable resistance line 3A exposed by the trench T may be damaged.

The row lines 6A may be located in the openings OP, respectively, and may be separated from each other. The conductive layer 6 may be over-etched to ensure that the row lines 6A are separated from each other. As a result, sidewalls of the row lines 6A may be recessed compared to sidewalls of the cell lines CL by a first distance D in the first direction I. The row line 6A may include a first sidewall SW1 extending in the first direction I and a second sidewall SW2 extending in the second direction II. The second sidewall SW2, defined by a wet etching process, may have greater surface roughness than the first sidewall SW1.

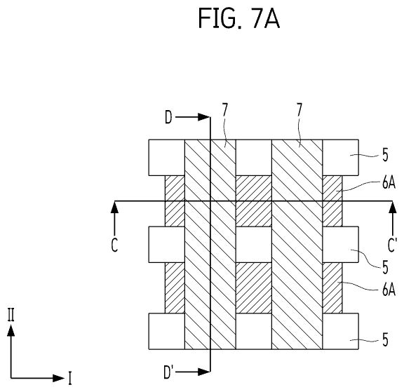

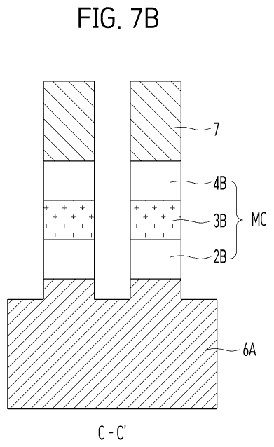

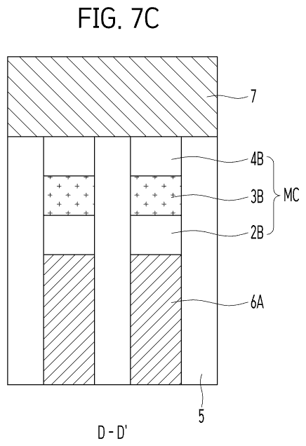

Referring to FIGS. 7A to 7C, column lines 7 may be formed. The column lines 7 may be located on the cell lines CL and the first gap-fill insulating layers 5, and may extend in the second direction II.

Subsequently, memory cells MC may be formed by etching the cell lines CL and the first gap-fill insulating layers 5. The memory cells MC may be located in intersection regions between the row lines 6A and the column lines 7. Each of the memory cells MC may include a first electrode 2B, a variable resistance layer 3B, and a second electrode 4B. If a sidewall of the variable resistance line 3A is damaged by the chemicals including the Group XVII element during the etching process of the conductive layer 6 as described above, the damaged portion of the variable resistance line 3A may be removed during the etching of the cell lines CL to form the memory cells MC. Alternatively, the damaged portion may be included in the memory cell MC, and the memory cell including the damaged portion may be used as a dummy memory cell.

According to the manufacturing method described above, the row lines 6A may be formed using a replacement process for replacing the sacrificial lines 1A with the conductive layer 6. Because a sidewall of the variable resistance line 3A is protected by the first gap-fill insulating layer 5 in the process of etching the conductive layer 6, damage to the variable resistance line 3A may be reduced or minimized. In addition, even though the variable resistance line 3A is exposed to the chemicals including the Group XVII element in the process of etching the conductive layer 6, the amount of the conductive layer that is etched may be reduced compared to a case where the row lines are formed by directly patterning the conductive layer. By forming the row lines 6A using the replacement process, it is possible to reduce a time for which the variable resistance line 3A is exposed in the process of etching the conductive layer 6. Consequently, this approach helps to reduce or prevent damage to the variable resistance line 3A.

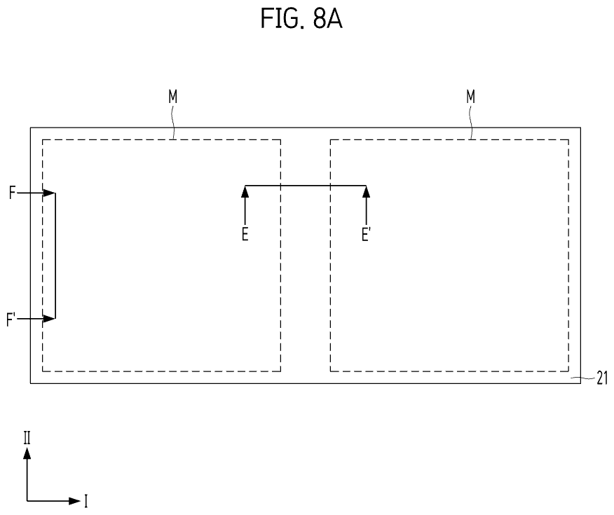

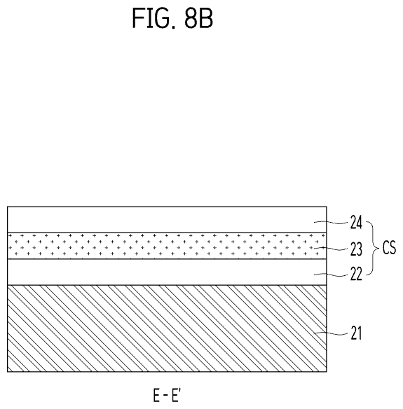

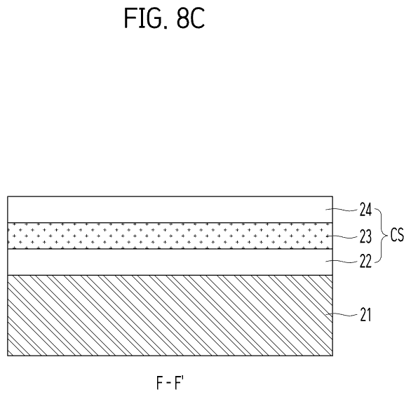

FIGS. 8A, 9A, 10A, 11A, 12A, 13A, and 14A, FIGS. 8B, 9B, 10B, 11B, 12B, 13B, and 14B, and FIGS. 8C, 9C, 10C, 11C, 12C, 13C, and 14C describe a manufacturing method of a semiconductor device in accordance with an embodiment. FIGS. 8A, 9A, 10A, 11A, 12A, 13A, and 14A are layout diagrams, FIGS. 8B, 9B, 10B, 11B, 12B, 13B, and 14B are cross-sectional views taken along lines E-E′ of FIGS. 8A, 9A, 10A, 11A, 12A, 13A, and 14A, and FIGS. 8C, 9C, 10C, 11C, 12C, 13C, and 14C are cross-sectional views taken along lines F-F′ of FIGS. 8A, 9A, 10A, 11A, 12A, 13A, and 14A. Hereinafter, the content overlapping with the previously described content may be omitted.

Referring to FIGS. 8A to 8C, a sacrificial layer 21 may be formed. The sacrificial layer 21 may be used to be replaced with row lines in a subsequent process. For example, the sacrificial layer 21 may be formed over a substrate (not shown). The substrate may include a lower structure such as a peripheral circuit and an insulating layer. Regions where a plurality of mats are to be formed may be defined on the substrate, and the sacrificial layer 21 may be formed to cover the regions where the plurality of mats M are to be formed.

Subsequently, a cell stack CS including a variable resistance layer 23 may be formed on the sacrificial layer 21. For example, the cell stack CS may include a first electrode layer 22, a variable resistance layer 23, and a second electrode layer 24, and the variable resistance layer 23 may be located between the first electrode layer 22 and the second electrode layer 24 in a stack direction corresponding to the third direction.

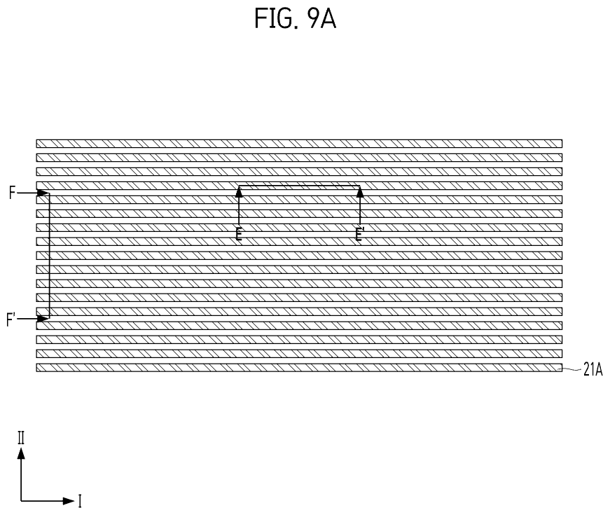

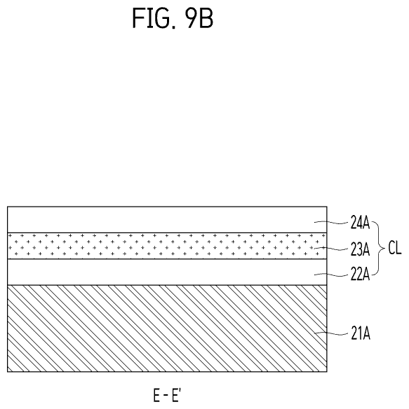

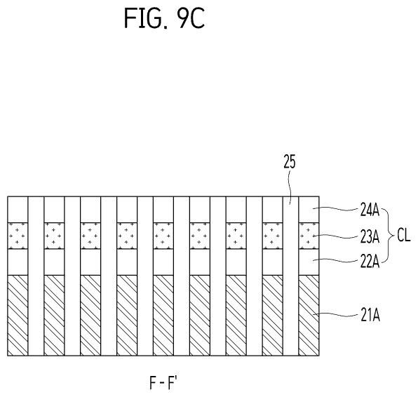

Referring to FIGS. 9A to 9C, cell lines CL may be formed by etching the cell stack CS. The cell lines CL may extend in the first direction I. Each of the cell lines CL may include a first electrode line 22A, a variable resistance line 23A, and a second electrode line 24A. Subsequently, sacrificial lines 21A may be formed by etching the sacrificial layer 21. The sacrificial lines 21A may extend in the first direction I. Subsequently, first gap-fill insulating layers 25 may be formed between the cell lines CL and between the sacrificial lines 21A. The first gap-fill insulating layers 25 may extend in the first direction I.

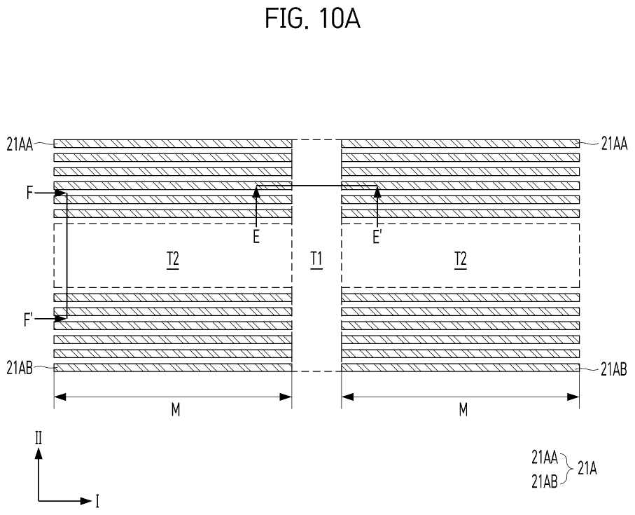

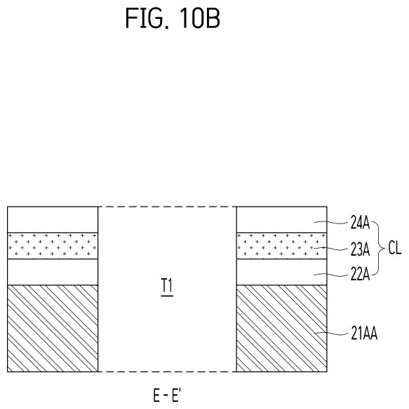

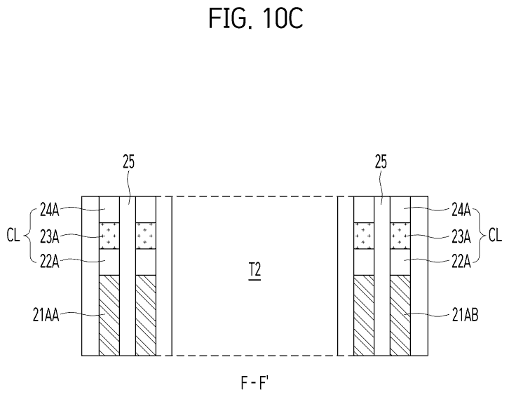

Referring to FIGS. 10A to 10C, a first trench T1 may be formed by etching the cell lines CL, the sacrificial lines 21A, and the first gap-fill insulating layers 25. The first trench T1 may extend in the second direction II, and may be located between two mats M adjacent to each other in the first direction I. That is, the two adjacent mats M in the first direction I may be defined by the first trench T1. The sacrificial lines 21A may be separated in mat units by forming the first trench T1. The sacrificial lines 21A may be exposed by the first trench T1.

A second trench T2 may be formed by etching the cell lines CL, the sacrificial lines 21A, and the first gap-fill insulating layers 25. The second trench T2 may be located inside the mat M, and may define a region where contact plugs are to be formed. For example, the second trench T2 may divide the sacrificial lines 21A into first sacrificial lines 21AA and second sacrificial lines 21AB in the second direction II. The second trench T2 may or may not expose the sacrificial lines 21A. The first trench T1 and the second trench T2 may be formed simultaneously or formed by separate processes.

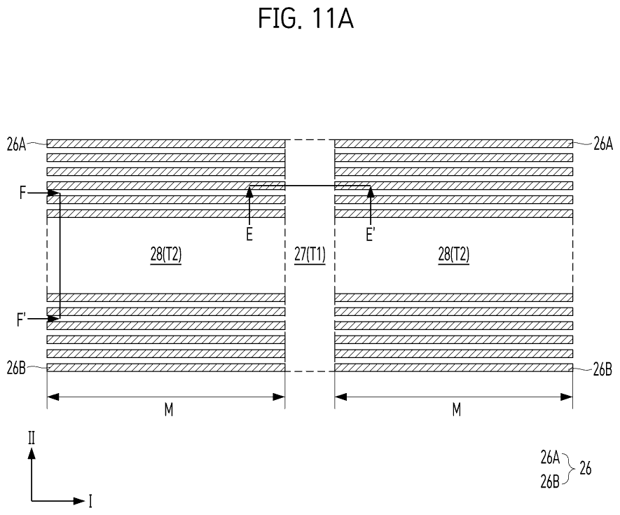

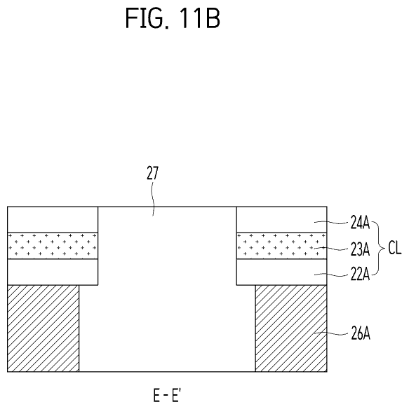

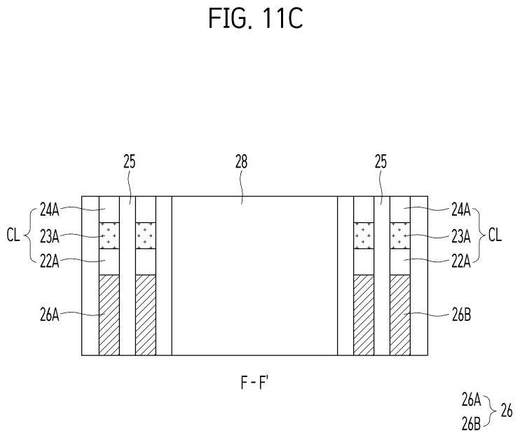

Referring to FIGS. 11A to 11C, the sacrificial lines 21A may be replaced with row lines 26 through at least one of the first trench T1 or the second trench T2. The row lines 26 may include first row lines 26A and second row lines 26B. The first sacrificial lines 21AA may be replaced with the first row lines 26A, and the second sacrificial lines 21AB may be replaced with the second row lines 26B. A sidewall of the row line 26 may be recessed compared to a sidewall of the cell line CL as shown in FIG. 11B.

Subsequently, a second gap-fill insulating layer 27 may be formed in the first trench T1. A third gap-fill insulating layer 28 may be formed in the second trench T2. The second gap-fill insulating layer 27 and the third gap-fill insulating layer 28 may be formed simultaneously or formed by separate processes.

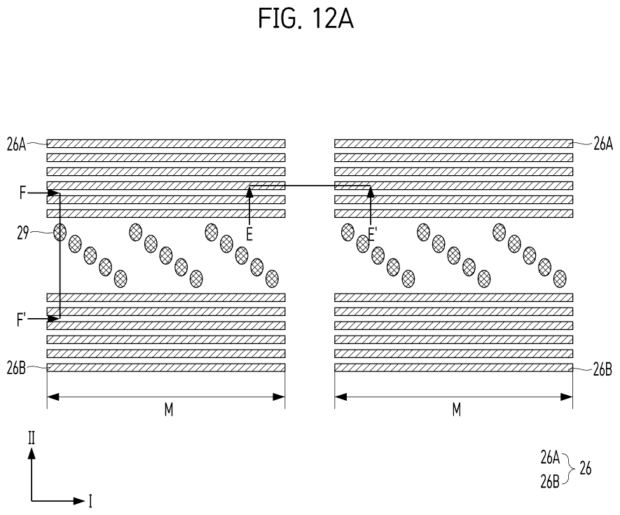

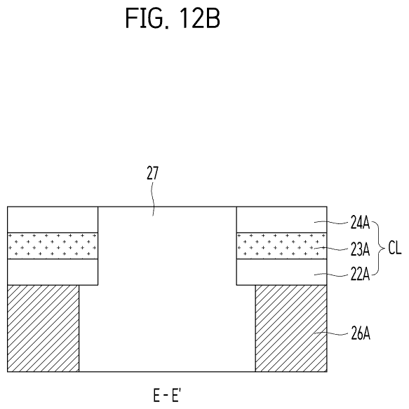

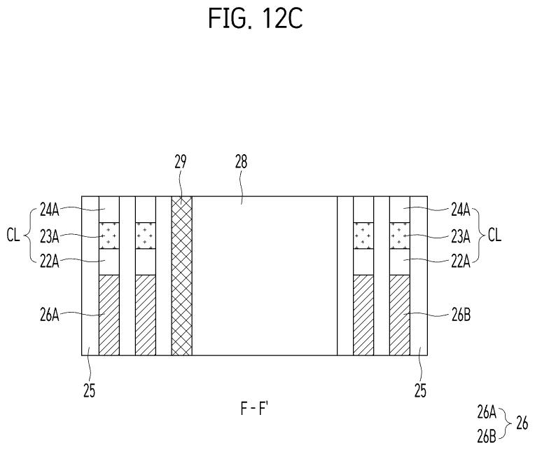

Referring to FIGS. 12A to 12C, contact plugs 29 may be formed. The contact plugs 29 may be located inside the mat M, and may be located between the first row line 26A and the second row line 26B adjacent to each other in the second direction II. The contact plugs 29 may extend through the third gap-fill insulating layer 28, and may be arranged in a diagonal direction.

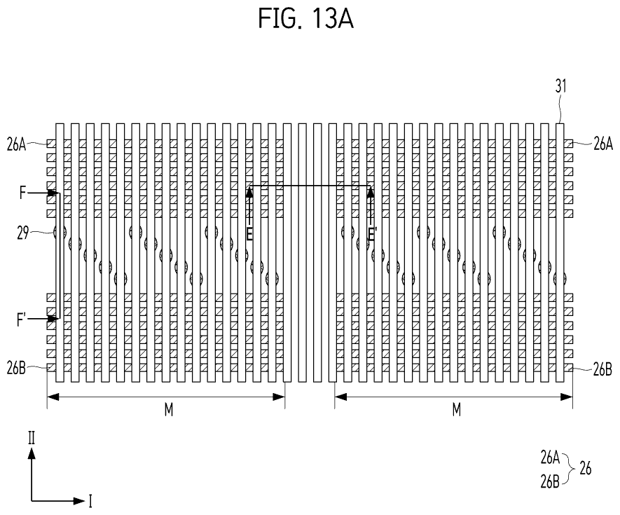

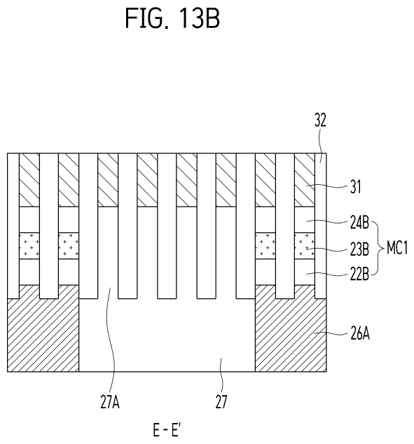

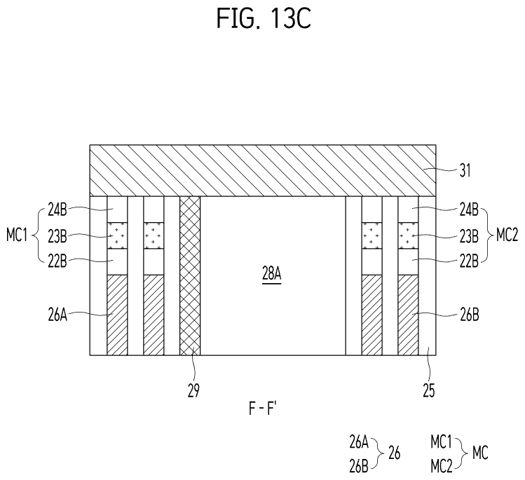

Referring to FIGS. 13A to 13C, column lines 31 may be formed. The column lines 31 may be located on the cell lines CL, the first gap-fill insulating layers 25, the second gap-fill insulating layer 27, and the third gap-fill insulating layer 28, and may extend in the second direction II. The column lines 31 may be connected to the contact plugs 29, respectively. The column lines 31 located between the mats M adjacent to each other in the first direction I may not be connected to the contact plugs 29.

Subsequently, memory cells MC may be formed by etching the cell lines CL and the first gap-fill insulating layers 25. Each of the memory cells MC may include a first electrode 22B, a variable resistance layer 23B, and a second electrode 24B. The memory cells MC may include first memory cells MC1 and second memory cells MC2. The first memory cells MC1 may be formed between the first row lines 26A and the column lines 31, and the second memory cells MC2 may be formed between the second row lines 26B and the column lines 31.

The second gap-fill insulating layer 27 may be etched between the mats M adjacent to each other in the first direction I, thereby forming first insulating lines 27A. The first insulating lines 27A may extend in the second direction II, and may each have substantially the same width as the column lines 31. Inside the mat M, the third gap-fill insulating layer 28 may be etched, thereby forming second insulating lines 28A. The second insulating lines 28A may extend in the second direction II, and may each have substantially the same width as the column lines 31.

Subsequently, fourth gap-fill insulating layers 32 may be formed between the column lines 31 and between the memory cells MC arranged in the first direction I. The fourth gap-fill insulating layers 32 may also be formed between the first insulating lines 27A and between the column lines 31.

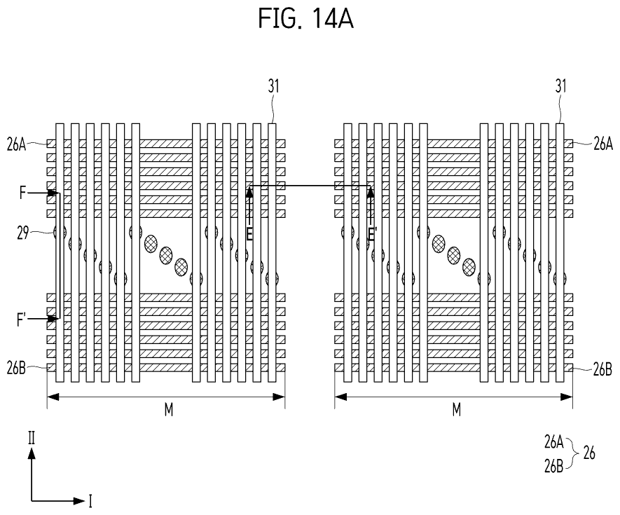

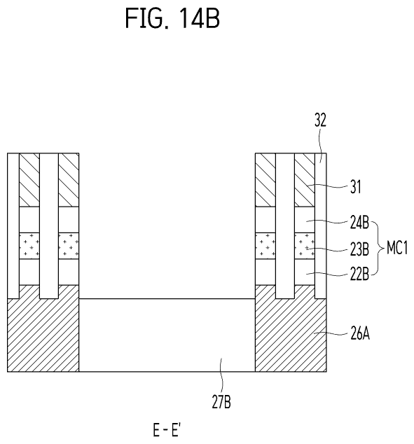

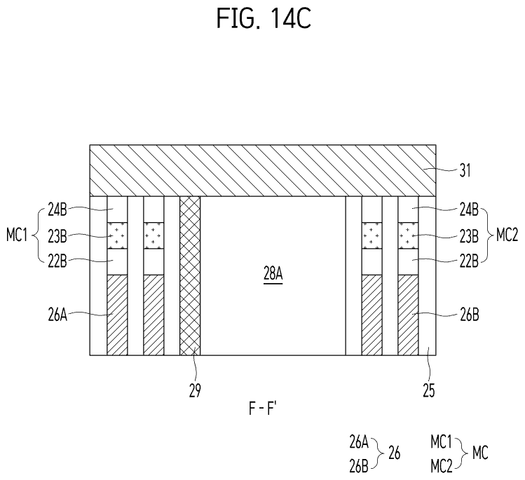

Referring to FIGS. 14A to 14C, the column lines 31 located between the mats M adjacent to each other in the first direction I may be removed. The column lines 31 overlapping with the first insulating lines 27A may be removed. The first insulating lines 27A located between the mats M adjacent to each other in the first direction I may be removed. At least one of the column lines 31 located within the mat M may be removed to expose at least one contact plug 29 disposed beneath that column line 31. This process secures a region where an interconnection structure connected to peripheral circuits can be formed.

According to the manufacturing method described above, the sacrificial lines 21A may be separated in mat M units by forming the first trench T1. In addition, the sacrificial lines 21A may be replaced with the row lines 26 through the first trench T1. Accordingly, even though a trench for a replacement process is not formed separately, the replacement process may be performed using the first trench T1.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A manufacturing method of a semiconductor device, the manufacturing method comprising:
forming a sacrificial layer;
forming a cell stack on the sacrificial layer in a third direction, the cell stack including a variable resistance layer;
etching the cell stack to form cell lines that extend in a first direction perpendicular to the third direction;
etching the sacrificial layer to form sacrificial lines that extend in the first direction;
forming first gap-fill insulating layers between the cell lines and between the sacrificial lines; and
replacing the sacrificial lines with row lines.

2. The manufacturing method of claim 1, wherein the replacing of the sacrificial lines with the row lines comprises:
etching the cell lines, the sacrificial lines, and the first gap-fill insulating layers to form a first trench that extends in a second direction intersecting the first direction and perpendicular to the third direction;
removing the sacrificial lines exposed through the first trench to form openings; and
forming the row lines in the openings.

3. The manufacturing method of claim 2, wherein the forming of the row lines comprises:
depositing a conductive layer to fill the openings and extend into the first trench; and
removing the conductive layer deposited in the first trench to form the row lines that correspond to the conductive layer remaining in the openings.

4. The manufacturing method of claim 3, wherein the etching of the conductive layer is performed using chemicals that include a Group XVII element.

5. The manufacturing method of claim 4, wherein sidewalls of the row lines are recessed compared to sidewalls of the cell lines in the first direction.

6. The manufacturing method of claim 2, wherein the semiconductor device includes multiple mats, and the first trench is located between mats adjacent to each other in the first direction.

7. The manufacturing method of claim 2, further comprising forming a second gap-fill insulating layer in the first trench.

8. The manufacturing method of claim 7, further comprising:
forming column lines on the cell lines and the second gap-fill insulating layer, the column lines extending in the second direction;
and forming memory cells by etching the cell lines, the memory cells being located in intersection regions between the row lines and the column lines.

9. The manufacturing method of claim 8, further comprising:
forming insulating lines by etching the second gap-fill insulating layer, the insulating lines extending in the second direction;
removing the column lines located on the insulating lines; and
removing the insulating lines.

10. The manufacturing method of claim 9, wherein the semiconductor device includes multiple mats, and in the removing of the column lines, the column lines located between mats adjacent to each other in the first direction are removed.

11. The manufacturing method of claim 1, wherein each of the row lines includes a first sidewall extending in the first direction and a second sidewall extending in a second direction intersecting the first direction, and the second sidewall exhibits greater surface roughness than the first sidewall.

12. The manufacturing method of claim 1, further comprising:
etching the cell lines, the sacrificial lines, and the first gap-fill insulating layers to form a second trench that extends in the first direction;
forming a third gap-fill insulating layer in the second trench; and
forming contact plugs in the third gap-fill insulating layer.

13. The manufacturing method of claim 1, wherein the sacrificial layer includes nitride.

14. A manufacturing method of a semiconductor device, the manufacturing method comprising:
forming a sacrificial layer;
forming a cell stack on the sacrificial layer in a third direction, the cell stack including a variable resistance layer;
etching the cell stack to form cell lines that extend in a first direction;
etching the sacrificial layer to form sacrificial lines that extend in the first direction;
etching the cell lines and the sacrificial lines to form a first trench that extend in a second direction intersecting the first direction, the first and second directions being perpendicular to the third direction;
removing the sacrificial lines exposed through the first trench to form openings;
forming a conductive layer in the openings and the first trench; and
forming row lines by removing the conductive layer in the first trench, the row lines corresponding to the conductive layer remaining in the openings, respectively.

15. The manufacturing method of claim 14, wherein, in the forming of the first trench, the sacrificial lines are separated in mat units by the first trench.

16. The manufacturing method of claim 14, further comprising:
forming column lines over the row lines and the cell lines, the column lines extending in the second direction; and
forming memory cells by etching the cell lines, the memory cells being located in intersection regions between the row lines and the column lines.

17. The manufacturing method of claim 14, further comprising:
etching the cell lines and the sacrificial lines to form a second trench that extend in the first direction;
forming a gap-fill insulating layer in the second trench; and
forming contact plugs extending through the gap-fill insulating layer.

18. The manufacturing method of claim 17, further comprising:
forming column lines respectively connected to the contact plugs and extending in the second direction; and
forming memory cells by etching the cell lines, the memory cells being located in intersection regions between the row lines and the column lines.

19. A semiconductor device comprising:
a first row line extending in a first direction and including a first sidewall extending in the first direction and a second sidewall extending in a second direction intersecting the first direction, the second sidewall exhibiting greater surface roughness than the first sidewall;
a column line extending in the second direction; and
a first memory cell connected to and disposed between the first row line and the column line.

20. The semiconductor device of claim 19, wherein the first memory cell comprises:
a first electrode electrically connected to the first row line;
a second electrode electrically connected to the column line; and
a variable resistance layer located between the first electrode and the second electrode.

21. The semiconductor device of claim 19, further comprising:
a second row line spaced apart from the first row line in the second direction and extending in the first direction; and
a second memory cell connected to and disposed between the column line and the second row line.

22. The semiconductor device of claim 21, further comprising a contact plug located between the first row line and the second row line and connected to the column line.

23. A semiconductor device comprising row lines manufactured by the method of claim 1,
wherein each of the row lines extends in a first direction and includes a first sidewall extending in the first direction and a second sidewall extending in a second direction intersecting the first direction, the second sidewall exhibiting greater surface roughness than the first sidewall.
